(19) United States
(12) Patent Application Publication
(10) Pub. No.: US 2009/0230405 A1
(43) Pub. Date: Sep. 17, 2009

(54) Diode having Schottky junction and PN junction and method for manufacturing the same

(75) Inventors: Takeo Yamamoto, Nishikamo-gun (JP); Takeshi Endo, Obu-city (JP); Masaki Konishi, Toyota-city (JP); Hirokazu Fujiwara, Nishikamo-gun (JP); Yukihiko Watanabe, Nagoya-city (JP); Takashi Katsuno, Ichinomiya-city (JP); Masayasu Ishiko, Nagoya-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/382,369

(22) Filed: Mar. 13, 2009

(30) Foreign Application Priority Data
Mar. 17, 2008 (JP) 2008-68260

(51) Int. Cl. H01L 29/24; H01L 21/04

(52) U.S. Cl. 257/77; 438/571; 438/582; 257/E29.104; 257/E21.062

(57) ABSTRACT

A manufacturing method of a diode includes: forming a P type semiconductor film on a N type semiconductor layer with a crystal growth method; forming a first metallic film on the P type semiconductor film so that the first metallic film contacts the P type semiconductor film with an ohmic contact; forming a mask having an opening on the first metallic film; etching a part of the first metallic film and a part of the P type semiconductor film via the opening so that a part of the N type semiconductor layer is exposed; and forming a second metallic film on the part of the N type semiconductor layer so that the second metallic film contacts the N type semiconductor layer with a Schottky contact.

### CROSS REFERENCE TO RELATED APPLICATION

This application is based on Japanese Patent Application No. 2008-68260 filed on Mar. 17, 2008, the disclosure of which is incorporated herein by reference.

### FIELD OF THE INVENTION

The present invention relates to a diode having a Schottky junction and a PN junction and a method for manufacturing the same.

### BACKGROUND OF THE INVENTION

A conventional Schottky diode includes a metal electrode for a Schottky junction connecting to a surface of a N conductive type semiconductor region. Further, a P conductive type semiconductor region is dispersively arranged on the surface of the N conductive type semiconductor region. This type of diode is defined as a JBS diode (i.e., junction barrier Schottky diode). The JBS diode is disclosed in, for example, JP-A-H10-321879.

FIG. 9 shows a JBS diode 100 according to a prior art. The diode 100 includes a semiconductor substrate 103. The substrate 103 has a N⁺ conductive type cathode region 110 having a N type impurity with high impurity concentration, a N conductive type region 112 and a P conductive type region 114. The P conductive type semiconductor region 114 is divided into multiple parts, which are dispersively arranged on the surface of the N conductive type region 112. A cathode electrode 104 is formed on the backside of the substrate 103. The cathode electrode 104 contacts a cathode region 110 with ohmic contact. An anode electrode 102 is formed on the foreside 103a of the substrate 103. The anode electrode 102 contacts the surface of the N conductive type semiconductor region 112 and the surface of the P conductive type semiconductor region 114 with Schottky junction Js.

When a voltage higher than the cathode electrode 104 is applied to the anode electrode 102, i.e., when a forward voltage is applied to the diode 100, the current flows from the anode electrode 102 to the cathode electrode 104 via the Schottky junction Js, the N conductive type semiconductor region 112 and the cathode region 110.

When the voltage higher than the anode electrode 102 is applied to the cathode electrode 104, i.e., when an inverse voltage is applied to the diode 100, a depletion layer expands from a P-N junction between the P conductive type semiconductor region 114 and the N conductive type semiconductor region 112. When multiple P conductive type semiconductor regions 114 are dispersively arranged on the surface of the N conductive type semiconductor region 112, the depletion layer widely expands, so that the diode 100 has high breakdown voltage. Thus, the breakdown voltage of the JBS diode 100 is superior to a conventional Schottky diode having no P conductive type semiconductor region 114.

In the diode 100, another Schottky junction Js is formed between the anode electrode 102 and the P conductive type semiconductor region 114. Although the diode 100 includes the P conductive type semiconductor region 114, the P-N junction diode between the P conductive type semiconductor region 114 and the N conductive-type semiconductor region 112 is not sufficiently utilized. If the P-N junction diode between the P conductive type semiconductor region 114 and the N conductive type semiconductor region 112 is sufficiently utilized, a resistance in the forward direction of the diode 100 is much reduced. However, the diode 100 does not provide this advantage.

It is preferred that the P conductive type semiconductor region 114 contacts the anode electrode 102 with ohmic contact so that the P-N junction diode between the P conductive type semiconductor region 114 and the N conductive type semiconductor region 112 functions as a PN junction diode. If the anode electrode 102 contacts the P conductive type semiconductor region 114 with ohmic contact, and further, the anode electrode 102 contacts the N conductive type semiconductor region 112 with a Schottky junction Js, the diode 100 may function as both of the JBS diode and the PN junction diode. However, there is no material for providing such anode electrode 102. Accordingly, when the anode electrode 102 is made of one metallic material, only one of the ohmic contact and the Schottky junction Js is provided.

Accordingly, by forming the anode electrode 102 from two types of metallic electrodes, the diode provides both of the PN junction diode and the JBS diode. For example, one metallic electrode is formed on the surface 103a of the substrate 103 to contact the surface of the P conductive type semiconductor region 114 with ohmic contact so that the one metallic electrode provides the anode electrode of the PN junction diode, and another metallic electrode is formed on the surface 103a of the substrate 103 to contact the surface of the N conductive type semiconductor region 112 with Schottky contact so that the other one metallic electrode provides the anode electrode of the JBS diode. Thus, the diode provides both of the JBS diode and the PON junction diode.

In the conventional diode 100, the P conductive type semiconductor region 114 and the N conductive type semiconductor region 112 are arranged on the surface 103a of the semiconductor substrate 103. Thus, the method for forming two metallic electrodes separately is complicated. Specifically, the P conductive type semiconductor region 114 is selectively formed on a part of the surface 103a of the substrate 103, and the metallic electrode contacting the P conductive type semiconductor region 114 with ohmic contact is selectively formed on the P conductive type semiconductor region 114. For example, ions are implanted on the selected part of the surface 103a of the substrate 103 so that the P conductive type semiconductor region 114 is formed. Then, the metallic electrode for the ohmic contact is selectively formed on the selected part of the surface 103a of the substrate 103, on which the P conductive type semiconductor region 114 is formed. Here, a step for limiting the ion implantation area and a step for limiting the metallic electrode forming area are different from each other. Thus, these steps are difficult and complicated to perform.

Thus, it is required to easily and simply manufacture the diode providing both of the JBS diode and the PN junction diode in such a manner that the one metallic electrode is formed on the N conductive type semiconductor region and the other metallic electrode is formed on the P conductive type semiconductor region.

### SUMMARY OF THE INVENTION

In view of the above-described problem, it is an object of the present disclosure to provide a method for manufacturing a diode having a Schottky junction and a PN junction. It is another object of the present disclosure to provide a diode having a Schottky junction and a PN junction.

According to a first aspect of the present disclosure, a method for manufacturing a diode includes: forming a P conductive type semiconductor film on a N conductive type semiconductor layer with a crystal growth method; forming a first metallic film on the P conductive type semiconductor film so that the first metallic film contacts the P conductive type semiconductor film with an ohmic contact; forming a mask having an opening on the first metallic film; etching a part of the first metallic film and a part of the P conductive type semiconductor film via the opening of the mask so that a part of the N conductive type semiconductor layer is exposed; and forming a second metallic film on the part of the N conductive type semiconductor layer so that the second metallic film contacts the N conductive type semiconductor layer with a Schottky contact.

In the above method, a step for dispersively forming the P conductive type semiconductor film on the N conductive type semiconductor layer and a step for selectively forming the first metallic film on the P conductive type semiconductor film are performed at the same time. Thus, the diode having the Schottky diode structure and the PN junction diode structure is easily manufactured.

According to a second aspect of the present disclosure, a diode includes: a cathode layer; a N conductive type layer arranged on the cathode layer; a plurality of P conductive type regions arranged on the N conductive type layer, wherein the plurality of P conductive type regions is separated from each other by a predetermined distance; a plurality of ohmic electrodes, each of which is arranged on a corresponding P conductive type region; and a Schottky electrode covering a part of the N conductive type layer, which is exposed from the plurality of P conductive type regions. The Schottky electrode further covers the plurality of P conductive type regions and the plurality of ohmic electrodes, and the cathode layer has a N conductive type.

The above diode having the Schottky diode structure and the PN junction diode structure is easily manufactured.

### BRIEF DESCRIPTION OF THE DRAWINGS

The above and other objects, features and advantages of the present invention will become more apparent from the following detailed description made with reference to the accompanying drawings. In the drawings:

FIG. 1 is a diagram showing a cross section of a diode according to an example embodiment;

FIG. 2-7 are diagrams showing a method for manufacturing the diode shown in FIG. 1;

FIG. 8 is a diagram showing a cross section of a diode according to another example embodiment; and

FIG. 9 is a diagram showing a cross section of a diode according to a prior art.

### DETAILED DESCRIPTION OF THE PREFERRED EMBODIMENTS

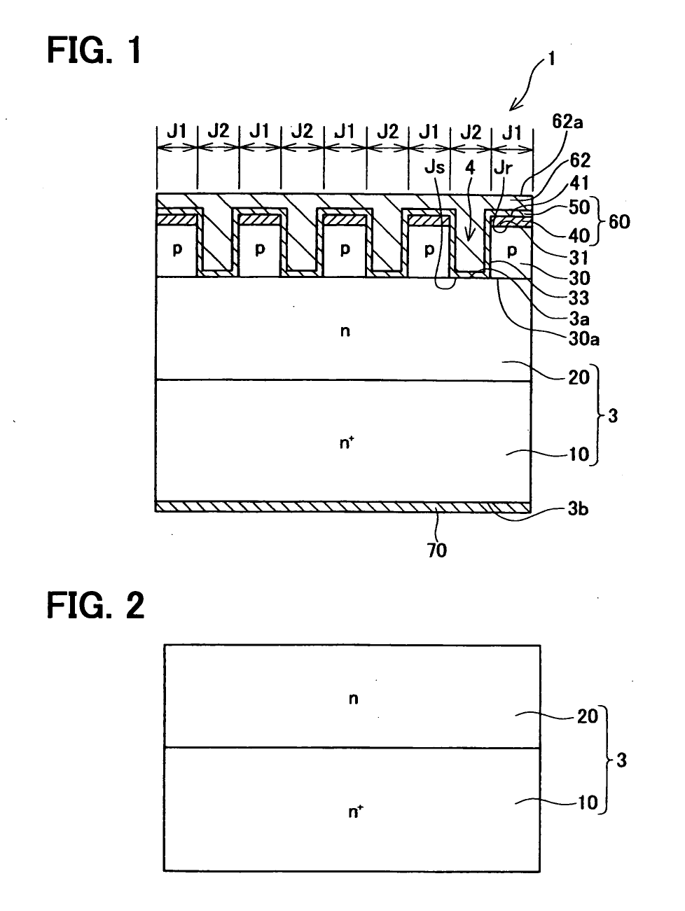

FIG. 1 shows a hybrid diode 1 having a JBS diode and a PN junction diode according to an example embodiment.

The diode 1 includes a SiC semiconductor substrate 3. A N⁺ type cathode region 10 and a N conductive type semiconductor region 20 are formed on the substrate 3 in this order. The diode 1 further includes multiple P conductive type semiconductor regions 30, which are formed on the surface of the N conductive type semiconductor region 20. The P conductive type semiconductor regions 30 are arranged on the N conductive type semiconductor region 20 at predetermined intervals so that a concavity 4 is formed between two adjacent P conductive type semiconductor regions 30. The diode 1 further includes an ohmic electrode 40 as a first metallic film, which is formed on a surface 31 of each P conductive type semiconductor region 30. The ohmic electrode 40 contacts the P conductive type semiconductor region 30 so that an ohmic junction Jr is formed therebetween. The ohmic electrode 40 is made of titanium, aluminum, nickel and their combination. Here, when the ohmic electrode 40 is made of two metallic materials, the ohmic electrode 40 is formed by stacking two metallic films.

The diode 1 includes a part of a surface of the N conductive type semiconductor region 20, on which no P conductive type semiconductor region 30 is formed so that the part of the surface of the N conductive type semiconductor region 20 is exposed from P conductive type semiconductor regions 30. Further, the diode 1 includes a sidewall 33 of the P conductive type semiconductor region 30, a sidewall of the ohmic electrode 40, and a Schottky electrode 50 for covering a surface 41 of the ohmic electrode 40. The Schottky electrode 50 is made of molybdenum, titanium or nickel. The Schottky electrode 50 contacts the part of the surface of the N conductive type semiconductor region 20, on which no P conductive type semiconductor region 30 is formed, so that a Schottky junction Js is formed therebetween. The Schottky electrode 50 and the ohmic electrode 40 provide an anode electrode 60. The anode electrode 60 is electrically coupled with both of the P conductive type semiconductor region 30 and the N conductive type semiconductor region 20. The diode 1 includes a surface wiring 62 for covering the surface of the anode electrode 60. The surface wiring 62 fills the concavity 4. The surface 62a of the surface wiring 62 is planarized. The surface wiring 62 is made of aluminum. The diode 1 further includes a cathode electrode 70, which contacts on the backside of the cathode region 10 with ohmic contact.

The diode 1 provides a structure of the PN junction diode, i.e., a PN junction diode region J1 and a structure of the Schottky diode, i.e., a Schottky diode region J2. In the PN junction diode region J1, the cathode electrode 70, the cathode region 10, the N conductive type semiconductor region 20, P conductive type semiconductor region 30, and the ohmic electrode 40 are stacked in this order. In the Schottky diode region J2, the cathode electrode 70, the cathode region 10, the N conductive type semiconductor region 20, and the Schottky electrode 50 are stacked in this order.

In general, the Schottky diode has a forward voltage drop, which is lower than the PN junction diode so that the Schottky diode flows the current between the anode and the cathode with the low forward voltage. The PN junction diode has a forward resistance, which is lower than the Schottky diode so that the current density between the anode and the cathode is high in a range of the high forward voltage. The diode 1 includes the PN junction diode region J1 and the Schottky diode region J2. Accordingly, the diode 1 can flows the current between the anode and the cathode with a low forward voltage since the Schottky diode region J2 functions. Further, the diode 1 flows the current with high density between the anode and the cathode when the forward voltage is high since the PN junction diode region J1 functions. The diode 1 has a low forward resistance between the anode and the cathode when the forward voltage is high. Thus, the diode 1 provides both of the characteristics of the Schottky diode and the characteristics of the PN junction diode.

When an inverse voltage is applied between the anode and the cathode, a depletion layer expands from the PN junction 30a between the P conductive type semiconductor region 30 and the N conductive type semiconductor region 20. The depletion layer covers a junction surface of the Schottky junction Js. Accordingly, the breakdown voltage of the diode 1 is high in case of an inverse bias. Thus, the diode 1 provides both of the JBS diode function and the PN junction diode function.

A method for manufacturing the diode 1 will be explained with reference to FIGS. 2-7.

As shown in FIG. 2, the cathode region 10 having the N⁺ conductive type is prepared. The impurity concentration of the cathode region 10 is 1×10¹⁸/cm³. The thickness of the cathode region 10 is 350 μm. The N conductive type semiconductor region 20 is formed on the surface of the cathode region 10 by a crystal growth method. The crystal growth is performed under reduced pressure at 1600° C. in a mixed gas atmosphere of a silane gas, a propane gas, a hydrogen gas and a nitrogen gas. The nitrogen gas introduces an impurity. The impurity concentration of the N conductive type semiconductor region 20 is 5×10¹⁵/cm³. The thickness of the N conductive type semiconductor region 20 is 15 μm. In this embodiment, the cathode region 10 and the N conductive type semiconductor region 20 provide the semiconductor substrate 3.

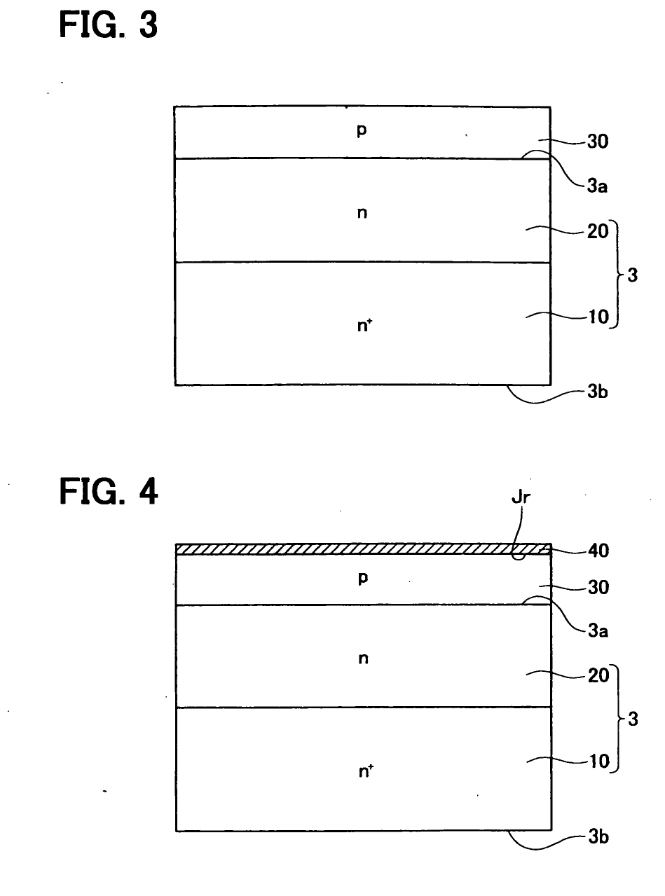

As shown in FIG. 3, the P conductive type semiconductor region 30 is formed on the surface of the N conductive type semiconductor region 20 by a crystal growth method. The crystal growth is performed under reduced pressure at 1600° C. in a mixed gas atmosphere of a silane gas, a propane gas, a hydrogen gas and a trimethyl-aluminum gas. The trimethyl-aluminum gas introduces an impurity. The impurity concentration of the P conductive type semiconductor region 30 is 1×10²⁰/cm³. The thickness of the P conductive type semiconductor region 30 is 1 μm.

As shown in FIG. 4, the ohmic electrode 40 is formed on the surface of the P conductive type semiconductor region 30 so that the ohmic electrode 40 and the P conductive type semiconductor region 30 provide the ohmic junction Jr. The ohmic electrode 40 is formed by an electron beam evaporation method. The thickness of the ohmic electrode 40 is 0.5 μm. The ohmic electrode 40 is made of titanium, aluminum, nickel or their combination. Here, when the ohmic electrode 40 is made of two metallic materials, the ohmic electrode 40 is formed by stacking two metallic films.

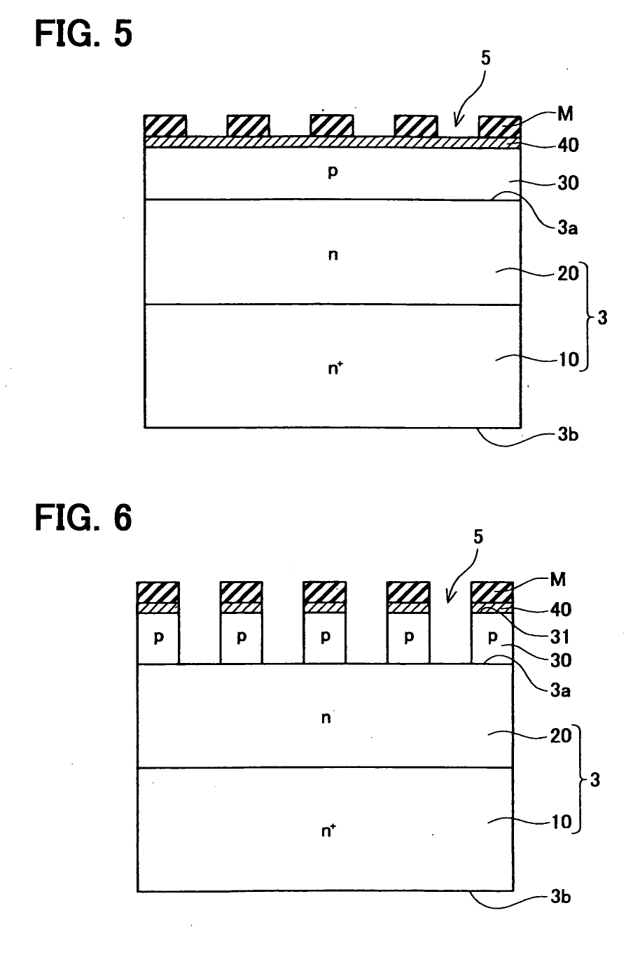

As shown in FIG. 5, a mask M having an opening 5 is formed on the surface of the ohmic electrode 40. The mask M is made of photo resist, and patterned by a photo lithography method.

As shown in FIG. 6, a part of the ohmic electrode 40 and a part of the P conductive type semiconductor region 30 are etched with using the opening 5 of the mask M. The part of the ohmic electrode 40 is dry-etched with using a chlorine based gas. The part of the P conductive type semiconductor region 30 is dry-etched with using a carbon tetrafluoride based gas. Then, the mask M is removed with using a sulphuric based remover.

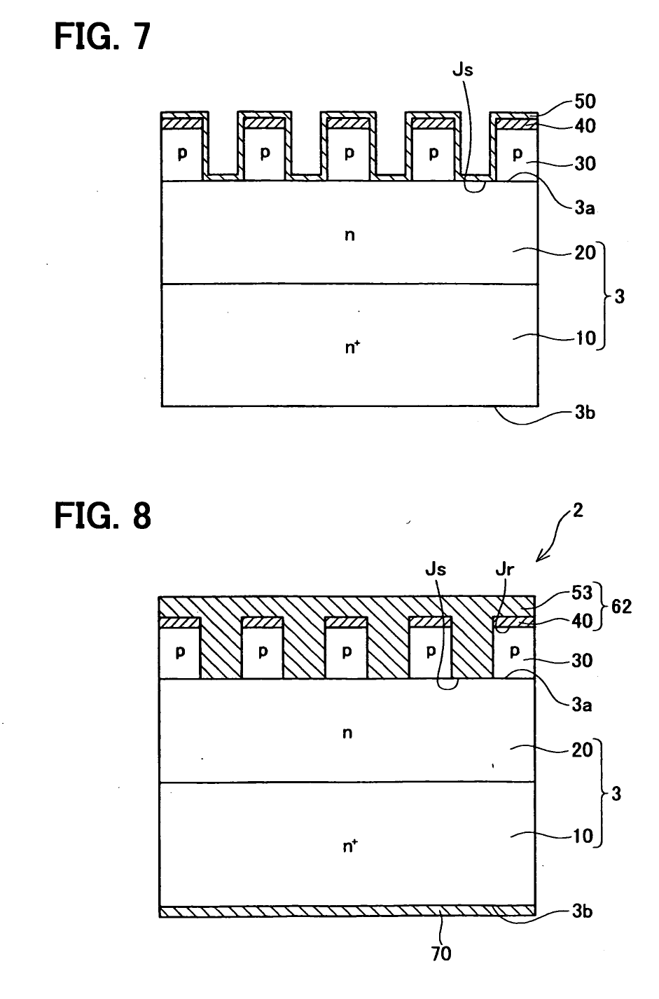

As shown in FIG. 7, a metallic film made of molybdenum, titanium or nickel is formed on a whole surface of the substrate 3 by an electron beam evaporation method. The thickness of the metallic film is 0.5 μm. Thus, the metallic film provides the Schottky electrode 50. The Schottky electrode 50 contacts a part of the surface of the n conductive type semiconductor region 20 with the Schottky junction Js. The Schottky electrode 50 is electrically connected to the ohmic electrode 40.

Then, as shown in FIG. 1, the surface wiring 62 is formed on the Schottky electrode 50 so that the surface wiring 62 fills the concavity 4. The surface wiring 62 is formed from aluminum by an evaporation method. The surface of the surface wiring 62 is planarized. Further, a nickel film is formed on the backside 3b of the substrate 3, i.e., the nickel film is formed on the cathode region 10, so that the cathode electrode 70 is formed.

When the part of the ohmic electrode 40 and the part of the P conductive type semiconductor region 30 are removed via the opening 5 of the mask M so that a part of the N conductive type semiconductor region 20 is exposed, as shown in FIG. 6, multiple P conductive type semiconductor regions 30 dispersively arranged on the surface 3a of the substrate is obtained, and further, the ohmic electrode 40 is selectively formed on the p conductive type semiconductor regions 30 at the same time. Thus, the step for forming the P conductive type semiconductor regions 30 dispersively on the N conductive type semiconductor region 20 and the step for forming the ohmic electrode 40 selectively on the surface 30 of the P conductive type semiconductor regions 30 are performed at the same time. The anode electrode 60 contacts the P conductive type semiconductor regions 30 with the ohmic junction Jr, and further, contacts the N conductive type semiconductor region 20 with the Schottky junction Js. The diode 1 having the Schottky diode region and the PN junction diode region is easily manufactured.

Further, as shown in FIG. 7, the Schottky electrode 50 is formed on the shole surface of the substrate 3. Thus, the Schottky electrode 50 is electrically connected to the ohmic electrode 40 at the same time when the Schottky electrode is formed on the N conductive type semiconductor region 20.

The P conductive type semiconductor region 30 is formed on the N conductive type semiconductor region 20 with using the crystal growth method. Accordingly, the P conductive type semiconductor region 30 is formed without implanting a P conductive type impurity. Further, it is not necessary to perform thermal treatment in order to activate the implanted P conductive type impurity. Thus, the surface of the N conductive type semiconductor region 20 is not substantially roughened. Therefore, a leak current in case of applying the inverse voltage is reduced, and the characteristics of the diode 1 are improved.

In the embodiment, the surface wiring 65 covers the whole surface of the Schottky electrode 50. Alternatively, as shown in FIG. 8, a Schottky electrode 53 instead of the Schottky electrode 50 and the surface wiring 62 may be formed in a diode 2. The surface of the Schottky electrode 50 is planarized. In this case, it is not necessary to form the surface wiring 62.

The above embodiments have the following features. An ohmic electrode is formed on a whole surface of a P conductive type semiconductor region. There is no step between the side of the P conductive type semiconductor region and the side of the ohmic electrode. The Schottky electrode covers the part of the N conductive type semiconductor region, on which the P conductive type semiconductor region is not arranged, the side of the P conductive type semiconductor region, the side of the ohmic electrode, and the surface of the ohmic electrode. Further, the surface wiring covers the surface of the Schottky electrode. The surface of the surface wiring is planarized. As shown in FIG. 8, the Schottky electrode covers the part of the N conductive type semiconductor region, on which the P conductive type semiconductor region is not arranged, the side of the P conductive type semiconductor region, the side of the ohmic electrode, and the surface of the ohmic electrode.

According to a first aspect of the present disclosure, a method for manufacturing a diode includes: forming a P conductive type semiconductor film on a N conductive type semiconductor layer with a crystal growth method; forming a first metallic film on the P conductive type semiconductor film so that the first metallic film contacts the P conductive type semiconductor film with an ohmic contact; forming a mask having an opening on the first metallic film; etching a part of the first metallic film and a part of the P conductive type semiconductor film via the opening of the mask so that a part of the N conductive type semiconductor layer is exposed; and forming a second metallic film on the part of the N conductive type semiconductor layer so that the second metallic film contacts the N conductive type semiconductor layer with a Schottky contact.

Here, in general, the Schottky contact is a junction having a Schottky barrier between semiconductor and metal. At the Schottky junction, the barrier height of the semiconductor is different from the barrier height of the metal. On the other hand, ohmic contact is a junction having no Schottky type barrier substantially. At the ohmic junction, there is no big difference between the barrier height of the semiconductor and the barrier height of the metal. Thus, when a forward voltage is applied to the ohmic junction, the current in proportion to the voltage according to the Ohm's law flows through the ohmic junction.

When the etching a part of the first metallic film and a part of the P conductive type semiconductor film is performed, the P conductive type semiconductor film is divided into multiple columns dispersively arranged on the N conductive type semiconductor layer, and the first metallic film is selectively arranged on each column of the P conductive type semiconductor film. Thus, a step for dispersively forming the P conductive type semiconductor film on the N conductive type semiconductor layer and a step for selectively forming the first metallic film on the P conductive type semiconductor film are performed at the same time. Thus, the diode having the Schottky diode structure and the PN junction diode structure is easily manufactured.

Alternatively, the method for manufacturing the diode may further include: removing the mask between the etching and the forming the second metallic film. In the forming the second metallic film, the second metallic film is formed on a side of the P conductive type semiconductor film, a side of the first metallic film and a surface of the first metallic film. In this case, the forming the second metallic film provides to electrically couple the first metallic film and the second metallic film.

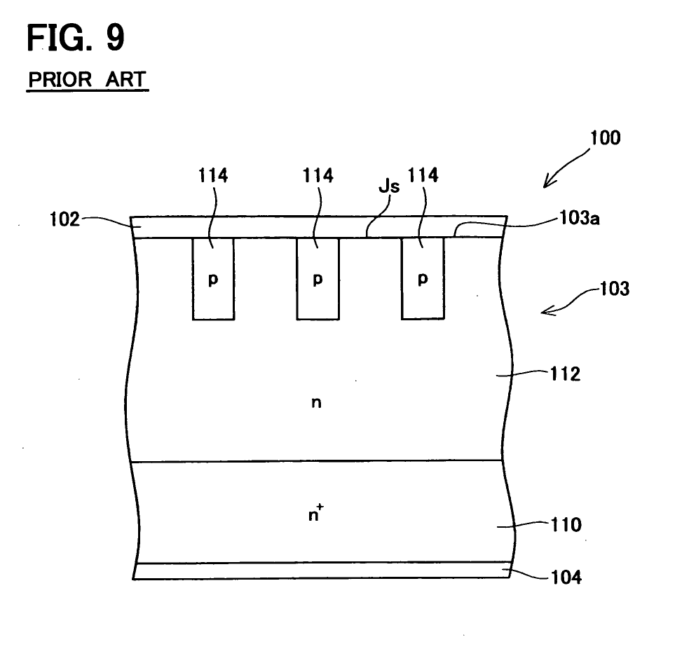

Alternatively, the N conductive type semiconductor layer and the P conductive type semiconductor film may be made of SiC. In the prior art, as shown in FIG. 9, the P conductive type semiconductor region 114 is formed such that a P type impurity is implanted on a part of the surface of the N conductive type semiconductor region 112, and then, the P type impurity is activated in a thermal treatment. When the P conductive type semiconductor region 114 is formed with using an ion implantation method, a defect may be formed in the P conductive type semiconductor region 114. Further, it is necessary to perform the heat treatment at a temperature equal to or higher than 1600° C. in order to activate the P type impurity when the P conductive type semiconductor region 114 is made of SiC. When the heat treatment is performed at a high temperature, the surface of the P conductive type semiconductor region 114 may be roughened since sublimation is occurred on the surface of the P conductive type semiconductor region 114. Accordingly, a leak current in a case where an inverse voltage is applied to the diode increases, so that performance of the diode is reduced. In the present embodiment, the P conductive type semiconductor film is formed on the N conductive type semiconductor layer by the crystal growth method. Accordingly, it is not necessary to perform an ion implantation step and a heat treatment. Thus, the leak current in a case where an inverse voltage is applied to the diode is reduced, so that performance of the diode is improved.

Alternatively, the first metallic film may be made of at least one of titanium, aluminum and nickel, and the second metallic film may be made of one of molybdenum, titanium and nickel. In this case, the first metallic film sufficiently contacts the P conductive type semiconductor film with ohmic contact. Further, the second metallic film sufficiently contacts the N conductive type semiconductor layer with Schottky contact.

Further, the method for manufacturing the diode may further include: forming a surface wiring on a whole surface of the second metallic film. The surface wiring is made of aluminum, and the P conductive type semiconductor film and the N conductive type semiconductor layer are made of SiC. Furthermore, the N conductive type semiconductor layer may have an impurity concentration around 5×10¹⁵/cm³. The P conductive type semiconductor film may have an impurity concentration around 1×10²⁰/cm³. The first metallic film has a thickness around 0.5 μm, and the second metallic film has a thickness around 0.5 μm.

According to a second aspect of the present disclosure, a diode includes: a cathode layer; a N conductive type layer arranged on the cathode layer; a plurality of P conductive type regions arranged on the N conductive type layer, wherein the plurality of P conductive type regions is separated from each other by a predetermined distance; a plurality of ohmic electrodes, each of which is arranged on a corresponding P conductive type region; and a Schottky electrode covering a part of the N conductive type layer, which is exposed from the plurality of P conductive type regions. The Schottky electrode further covers the plurality of P conductive type regions and the plurality of ohmic electrodes, and the cathode layer has a N conductive type.

The above diode having the Schottky diode structure and the PN junction diode structure is easily manufactured.

Alternatively, the ohmic electrode may be made of at least one of titanium, aluminum and nickel, and the Schottky electrode may be made of at least one of molybdenum, titanium and nickel. Each P conductive type region and the N conductive type layer may be made of SiC. Further, the diode may further include: a surface wiring arranged on a whole surface of the Schottky electrode. The surface wiring is made of aluminum. Furthermore, the cathode layer may have an impurity concentration around 1×10¹⁸/cm³, and the N conductive type layer may have an impurity concentration around 5×10¹⁵/cm³. Each P conductive type region may have an impurity concentration around 1×10²⁰/cm³. The ohmic electrode has a thickness around 0.5 μm, and the Schottky electrode has a thickness around 0.5 μm.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A method for manufacturing a diode comprising:
forming a P conductive type semiconductor film on a N conductive type semiconductor layer with a crystal growth method;
forming a first metallic film on the P conductive type semiconductor film so that the first metallic film contacts the P conductive type semiconductor film with an ohmic contact;
forming a mask having an opening on the first metallic film;
etching a part of the first metallic film and a part of the P conductive type semiconductor film via the opening of the mask so that a part of the N conductive type semiconductor layer is exposed; and
forming a second metallic film on the part of the N conductive type semiconductor layer so that the second metallic film contacts the N conductive type semiconductor layer with a Schottky contact.

2. The method for manufacturing the diode according to claim 1, further comprising:
removing the mask between the etching and the forming the second metallic film,
wherein, in the forming the second metallic film, the second metallic film is formed on a side of the P conductive type semiconductor film, a side of the first metallic film and a surface of the first metallic film.

3. The method for manufacturing the diode according to claim 1,
wherein the N conductive type semiconductor layer and the P conductive type semiconductor film are made of SiC.

4. The method for manufacturing the diode according to claim 1,
wherein the first metallic film is made of at least one of titanium, aluminum and nickel, and
wherein the second metallic film is made of one of molybdenum, titanium and nickel.

5. The method for manufacturing the diode according to claim 4, further comprising:
forming a surface wiring on a whole surface of the second metallic film,
wherein the surface wiring is made of aluminum, and
wherein the P conductive type semiconductor film and the N conductive type semiconductor layer are made of SiC.

6. The method for manufacturing the diode according to claim 5,
wherein the N conductive type semiconductor layer has an impurity concentration around 5×10¹⁵/cm³,
wherein the P conductive type semiconductor film has an impurity concentration around 1×10²⁰/cm³,
wherein the first metallic film has a thickness around 0.5 μm, and
wherein the second metallic film has a thickness around 0.5 μm.

7. A diode comprising:
a cathode layer;
a N conductive type layer arranged on the cathode layer;
a plurality of P conductive type regions arranged on the N conductive type layer, wherein the plurality of P conductive type regions is separated from each other by a predetermined distance;
a plurality of ohmic electrodes, each of which is arranged on a corresponding P conductive type region; and
a Schottky electrode covering a part of the N conductive type layer, which is exposed from the plurality of P conductive type regions,
wherein the Schottky electrode further covers the plurality of P conductive type regions and the plurality of ohmic electrodes, and
wherein the cathode layer has a N conductive type.

8. The diode according to claim 7,
wherein the ohmic electrode is made of at least one of titanium, aluminum and nickel,
wherein the Schottky electrode is made of at least one of molybdenum, titanium and nickel, and
wherein each P conductive type region and the N conductive type layer are made of SiC.

9. The diode according to claim 8, further comprising:
a surface wiring arranged on a whole surface of the Schottky electrode,
wherein the surface wiring is made of aluminum.

10. The diode according to claim 9,
wherein the cathode layer has an impurity concentration around 1×10¹⁸/cm³,
wherein the N conductive type layer has an impurity concentration around 5×10¹⁵/cm³,
wherein each P conductive type region has an impurity concentration around 1×10²⁰/cm³,
wherein the ohmic electrode has a thickness around 0.5 μm, and
wherein the Schottky electrode has a thickness around 0.5 μm.
